(19) United States
(12) Patent Application Publication
(10) Pub. No.: US 2009/0316745 A1
(43) Pub. Date: Dec. 24, 2009

(54) OPTICAL MODULE

(75) Inventors: Toshihiko Fukamachi, Kokubunji (JP); Takuma Ban, Kodaira (JP); Toshiki Sugawara, Kokubunji (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/465,726

(22) Filed: May 14, 2009

(30) Foreign Application Priority Data
Jun. 24, 2008 (JP) JP2008-163946

(51) Int. Cl. H01S 5/026; H01S 5/183

(52) U.S. Cl. 372/50.21; 372/50.124

(57) ABSTRACT

A laser diode has a horizontal cavity and a mirror attached to the horizontal cavity at an angle of substantially 45° or substantially 135°. The laser diode is mounted on a stem substantially horizontally with taking light vertically emitted to the horizontal cavity as an optical signal, and light horizontally emitted as an optical signal for monitoring, respectively. A photodetector is mounted on the stem substantially orthogonally and so as to let in the optical signal for monitoring.

### CROSS-REFERENCE TO RELATED APPLICATION

The present application claims priority from Japanese Patent Application No. JP 2008-163946 filed on Jun. 24, 2008, the content of which is hereby incorporated by reference into this application.

### TECHNICAL FIELD OF THE INVENTION

The present invention relates to an optical module, more particularly, a structure of an optical module with a monitoring function of a vertical emitting laser.

### BACKGROUND OF THE INVENTION

In the information communication field in recent years, installations of communication traffics for exchanging large size data in a high speed by using light has been rapidly implemented. Particularly, introduction of broadband access lines along with an explosive growth of the Internet has been accelerated, and a significant market rising of FTTH (Fiber To The Home) service has been recognized. One of FTTH optical transfer systems currently having increasing demands is PON (Passive Optical Network) system which shares one optical fiber with a plurality of users. According to the PON system, data sent from a station via one optical fiber is branched into 16 to 32 lines of optical fibers by a splitter to distribute to each user's home, thereby enabling a large reduction in the laid down cost of optical fibers. In addition, an ONU (Optical Network Unit) is installed as a terminal device for each of the users, and down stream signals (wavelength 1.5 μm) from the station to the user side and upstream signals (wavelength 1.3 μm) from the user side to the station are subjected to wavelength division multiplexing (WDM), thereby transferring upstream and downstream signals using a same optical fiber. The ONU has installed therein a dual-wavelength bi-directional optical module in which a CAN package module mounting a laser diode for sending upstream signals is mounted. Other than that, in the optical communication field, the CAN package module mounting a laser diode is also used for the XFP (10-Gigabit Small Form Factor Pluggable) module that is a standard of optical transmitting and receiving modules for 10 Gbit Ethernet. Also, in the information field, the CAN package module is used for optical disks and optical computing and further, in the measurement field, it is widely used as a light source for, for example, optical topography.

To realize the CAN package module, there are configurations of optical module having a monitoring function using a vertical cavity surface emitting laser (VCSEL) that is a part of a vertical emitting laser such as those disclosed in, for example, Japanese Patent Application Laid-Open Publication No. 2005-085942 (Patent Document 1) and Japanese Patent Application Laid-Open Publication No. 2005-086067 (Patent Document 2). The module includes at least: a vertical cavity surface emitting laser; an optical element such as a half mirror and a diffraction grating which reflects, refracts, or diffracts at least a part of light orthogonally emitted from the vertical cavity surface emitting laser; a package lid for fixing the optical element; and a photodetector horizontally mounted to the vertical cavity surface emitting laser, wherein the emitted light of the vertical cavity surface emitting laser is highly precisely adjusted by the optical element and the package lid to be guided to the photodetector, so that the amount of output light of the optical module and the amount of optical signal for monitoring the photodetector are stabilized.

### SUMMARY OF THE INVENTION

In the configurations of an optical module having a monitoring function using a surface emitting semiconductor device that is a part of a vertical emitting laser as mentioned above, there have been problems such as (i) an assembly precision is required in a positional relation of a laser diode and a photodetector and a position of a package lid leading to an increase of cost, (ii) use of a half-mirror and a diffraction grating poses a loss in optical output, and (iii) an increase in the number of parts such as optical members and an requirement of a special package lid.

In the present invention, a laser diode has a horizontal cavity and a mirror attached to the horizontal cavity at an angle of 45° or 35°. The laser diode is mounted on a stem substantially horizontally with taking light vertically emitted to the horizontal cavity as an optical signal, and light horizontally emitted as an optical signal for monitoring, respectively. The photodetector is mounted on the stem substantially orthogonally and so as to let in the optical signal for monitoring. In this manner, the above-mentioned problems are solved.

According to the embodiments of the present invention, an optical module having a monitoring function of a vertical emitting laser that is easy to assemble and capable of reducing cost with a reduced number of parts can be provided.

### BRIEF DESCRIPTIONS OF THE DRAWINGS

FIG. 1 is a perspective view of an optical module having a monitoring function of a horizontal cavity vertical emitting laser diode of a first embodiment of the present invention;

FIG. 2 is a cross-sectional view of an optical module having a monitoring function of a horizontal cavity vertical emitting laser diode of a second embodiment of the present invention;

FIG. 3 is a cross-sectional view of an optical module having a monitoring function of a horizontal cavity vertical emitting laser diode of a third embodiment of the present invention;

FIG. 4 is a diagram viewed from above of an optical module having a monitoring function of a horizontal cavity vertical emitting laser diode of a fourth embodiment of the present invention;

FIG. 5 is a diagram viewed from above of an optical module having a monitoring function of a horizontal cavity vertical emitting laser diode of a fifth embodiment of the present invention; and

FIG. 6 is a diagram viewed from above of the optical module having a monitoring function of the horizontal cavity vertical emitting laser diode of the fifth embodiment of the present invention.

### DESCRIPTIONS OF THE PREFERRED EMBODIMENTS

In the following, the embodiments will be described in detail. Note that, the accompanying drawings simply describe the present embodiments, and the illustrated sizes in these do not necessarily coincide with scales to be mentioned in the present embodiments.

### First Embodiment

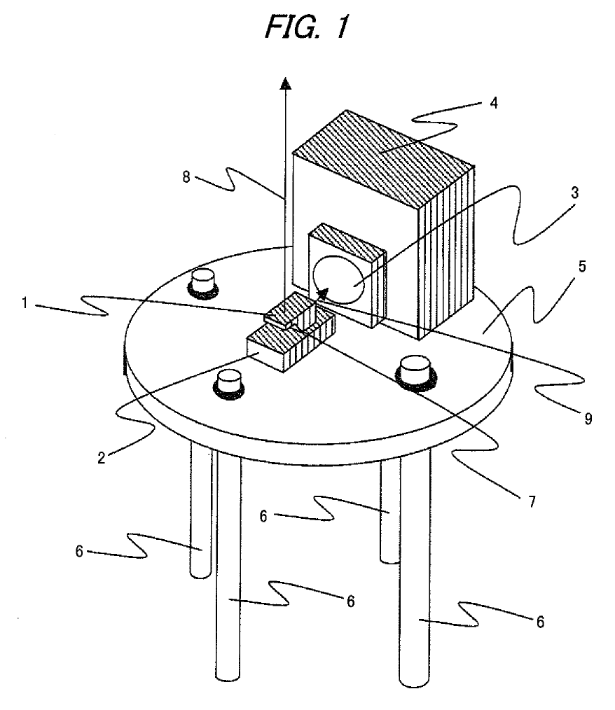

FIG. 1 is a perspective view of an optical module of a first embodiment of the present invention. A submount 2 substantially horizontally equipped with a horizontal cavity vertical emitting laser diode 1 is substantially horizontally mounted on a stem 5. A mount block 4 substantially horizontally equipped with a photodetector is substantially orthogonally mounted on the stem 5. The horizontal cavity vertical emitting laser diode 1 has installed thereinside a horizontal cavity and a mirror 7 provided at substantially 135° to the horizontal cavity. An optical signal 8 is emitted substantially orthogonally, and an optical signal for monitoring 9 is emitted substantially horizontally. The photodetector 3 is mounted so that the optical signal for monitoring 9 enters the photodetector 3.

An electric signal transmitted to the horizontal cavity vertical emitting laser diode 1 via a lead pin 6 is converted to an optical signal by the horizontal cavity vertical emitting laser diode 1, and transmitted to the outside as the optical signal 8. On the other hand, the optical signal for monitoring 9 is converted to an electric signal and so forth by the photodetector 3 to transfer information substantially a state of the horizontal cavity vertical emitting laser diode 1 and so forth to the outside via the lead pin 6. Note that, the horizontal cavity vertical emitting laser diode 1 has a same configuration also when it has installed thereinside a horizontal cavity and a mirror provided to the horizontal cavity at an angle of substantially 45°.

### Second Embodiment

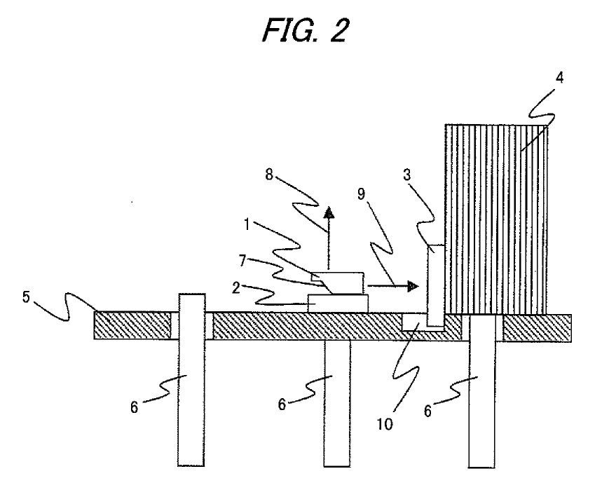

FIG. 2 is a cross-sectional view of an optical module according to a second embodiment of the present invention. A submount 2 substantially horizontally equipped with a horizontal cavity vertical emitting laser diode 1 is substantially horizontally mounted on a stem 5. The horizontal cavity vertical emitting laser diode 1 has installed thereinside a horizontal cavity and a mirror 7 provided at substantially 135° to the horizontal cavity. An optical signal 8 is emitted substantially orthogonally, and an optical signal for monitoring 9 is emitted substantially horizontally. A groove 10 is formed on the stem 5. The mount block 4 substantially horizontally equipped with the photodetector 3 is substantially orthogonally mounted to the stem 5 with inserting a part of the photodetector 3 in the groove 10 to adjust a height of the mount block 4 so that the optical signal for monitoring 9 can easily enter. Note that, the horizontal cavity vertical emitting laser diode 1 has a same configuration also when it has installed thereinside a horizontal cavity and a mirror provided to the horizontal cavity at an angle of substantially 45°.

### Third Embodiment

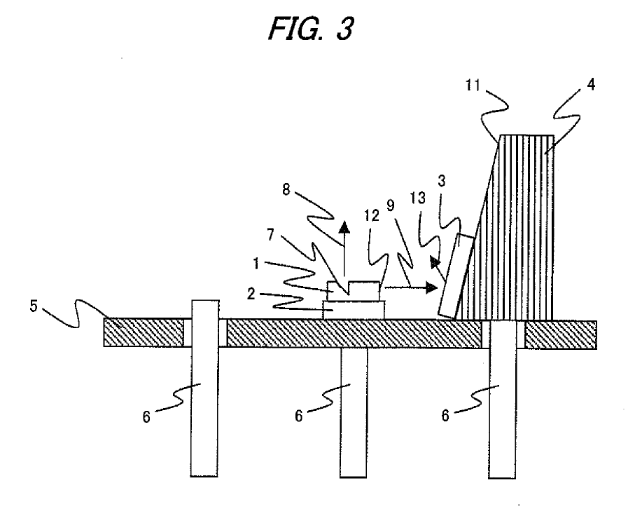

FIG. 3 is a cross-sectional view of an optical module according to a third embodiment of the present invention. A submount 2 substantially horizontally equipped with a horizontal cavity vertical emitting laser diode 1 is substantially horizontally mounted on a stem 5. A slope surface of mount block 11 is formed on a mount block 4. The mount block 4 equipped with a photodetector 3 on the slope surface of mount block 11 is substantially orthogonally mounted on the stem 5 not to let the slope surface of mount block 11 to be parallel to an end surface of horizontal cavity vertical emitting laser diode 12. The horizontal cavity vertical emitting laser diode 1 has installed thereinside a horizontal cavity and a mirror 7 provided at substantially 45° to the horizontal cavity. An optical signal 8 is emitted substantially orthogonally, and an optical signal for monitoring 9 is emitted substantially horizontally. The photodetector 3 is mounted so that the optical signal for monitoring 9 enters the photodetector 3.

Since the photodetector 3 and the end surface of horizontal cavity vertical emitting laser diode 12 are not parallel, a reflected optical signal 13 of the optical signal for monitoring 9 partly reflected on the photodetector 3 enters the end surface of horizontal cavity vertical emitting laser diode 12, thereby preventing a degradation of characteristics of the horizontal cavity vertical emitting laser diode 1. Note that, the horizontal cavity vertical emitting laser diode 1 has a same configuration also when it has installed thereinside a horizontal cavity and a mirror provided to the horizontal cavity at an angle of substantially 135°.

### Fourth Embodiment

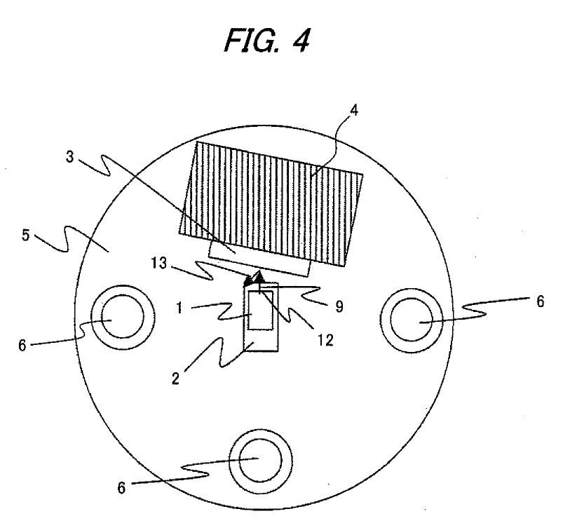

FIG. 4 is a diagram viewed from above of an optical module according to a fourth embodiment of the present invention. A submount 2 substantially horizontally equipped with a horizontal cavity vertical emitting laser diode 1 is substantially horizontally mounted on a stem 5. A mount block 4 substantially horizontally equipped with a photodetector 3 is substantially orthogonally mounted on the stem 5 not to let the photodetector 3 to be parallel to an end surface of horizontal cavity vertical emitting laser diode 12. Although not illustrated in FIG. 4, the horizontal cavity vertical emitting laser diode 1 has installed thereinside a horizontal cavity and a mirror 7 provided at substantially 45° or substantially 135° to the horizontal cavity. An optical signal 8 is emitted substantially orthogonally to the plane of the paper, and an optical signal for monitoring 9 is emitted substantially horizontally to the plane of the paper. The photodetector 3 is mounted so that the optical signal for monitoring 9 enters the photodetector 3.

Since the photodetector 3 and the end surface of horizontal cavity vertical emitting laser diode 12 are not parallel, a reflected optical signal 13 of the optical signal for monitoring 9 partly reflected on the photodetector 3 enters the end surface of horizontal cavity vertical emitting laser diode 12, thereby preventing a degradation of characteristics of the horizontal cavity vertical emitting laser diode 1.

### Fifth Embodiment

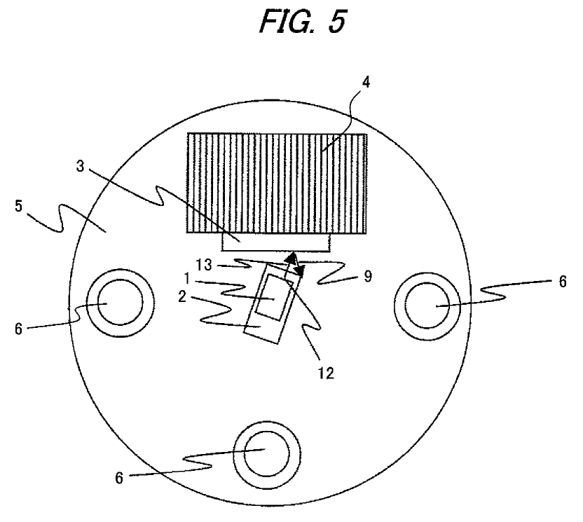

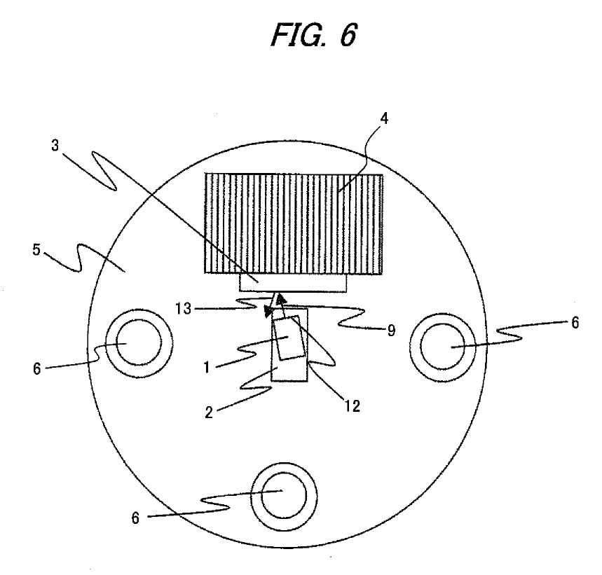

FIG. 5 and FIG. 6 are diagrams viewed from above of an optical module according to a fifth embodiment of the present invention. A mount block 4 substantially horizontally equipped with a photodetector 3 is substantially orthogonally mounted on a stem 5. A submount 2 substantially horizontally equipped with a horizontal cavity vertical emitting laser diode 1 is substantially horizontally mounted on a stem 5 not to let the photodetector 3 to be parallel to an end surface of horizontal cavity vertical emitting laser diode 12. Although not illustrated in FIG. 5 and FIG. 6, the horizontal cavity vertical emitting laser diode 1 has installed thereinside a horizontal cavity and a mirror 7 provided at substantially 45° or substantially 135° to the horizontal cavity. An optical signal 8 is emitted substantially orthogonally to the plane of the paper, and an optical signal for monitoring 9 is emitted substantially horizontally to the plane of the paper. The photodetector 3 is mounted so that the optical signal for monitoring 9 enters the photodetector 3.

Since the photodetector 3 and the end surface of horizontal cavity vertical emitting laser diode 12 are not parallel, a reflected optical signal 13 of the optical signal for monitoring 9 partly reflected on the photodetector 3 enters the end surface of horizontal cavity vertical emitting laser diode 12, thereby preventing a degradation of characteristics of the horizontal cavity vertical emitting laser diode 1. That is, returned optical signals can be prevented from entering an emission surface of a semiconductor laser device and the like. This is because, if the returned optical signals go back into the semiconductor laser device, it causes a degradation of characteristics of the device.

What is claimed is:

1. An optical module comprising a horizontal cavity and a mirror provided to the horizontal cavity with being tilted at an angle of substantially 135° or 135°, alternatively, substantially 45° or 45°, a vertical emitting laser being provided on a stem having emitted light from the horizontal cavity including light to be emitted in a substantially normal direction of an extending direction of the horizontal cavity as an optical signal and light emitted in a direction substantially parallel to the extending direction of the horizontal cavity as an optical signal for monitoring, and a photodetector for receiving the optical signal for monitoring being provided on the stem.

2. The optical module according to claim 1, wherein
the laser diode is provided on the stem so that the extending direction of the horizontal cavity and an extending direction of the stem are substantially parallel with each other, and the photodetector is provided on the stem so that an extending direction of a photo-detecting surface of the photodetector and a normal direction of the extending direction of the stem are substantially parallel to each other.

3. The optical module according to claim 2, wherein
a groove is provided on the stem in a normal direction to the extending direction of the stem, and a part of the photodetector is embedded in the groove.

4. The optical module according to claim 1, wherein
the photodetector is fixed to one surface of a mount block, and another surface of the mount block is fixed to a surface of the stem.

5. The optical module according to claim 1, wherein
an extending direction of a photo-detecting surface of the photodetector is not parallel with a normal direction with respect to a plane of the stem.

6. The optical module according to claim 1, wherein
a normal direction of a photo-detecting surface of the photodetector is not parallel with the extending direction of the horizontal cavity.
